(19) United States
(12) Patent Application Publication
(10) Pub. No.: US 2011/0084686 A1
(43) Pub. Date: Apr. 14, 2011

(54) NATURE TONE RECOGNIZING METHOD AND APPARATUS

(76) Inventor: Gang Zhang, Alpharetta, GA (US)

(21) Appl. No.: 12/577,204

(22) Filed: Oct. 11, 2009

(51) Int. Cl. G01R 23/00

(52) U.S. Cl. 324/76.19

(57) ABSTRACT

An apparatus and method to recognize tones from human singing or similar characteristics is described.

The method used to recognize the tone tries to mimic how human brain interprets tones and reduces errors by use multiple combinations of trial and error to get the closest frequency of the tone.

### BACKGROUND OF THE INVENTION

1. Field of the Invention

The invention relates to a method and an apparatus for tone recognition. The tone can be a human produced tone or any tone with characteristics of a human produced tone. The invention can be used as the first step to recognize/search music produced by human or other nature instruments.

2. Related Background Art

Tone recognition for machine generated sound is sample. For example, a 440 Hz sound will show as a single peak on the spectrum. However when the sound is generated by human, the place of the spectrum will vary and there will also be many peaks. Different tones can have overlapping peaks and is hard to differentiate.

### SUMMARY OF THE INVENTION

It is an object of the invention to identity the tone just as a human could. For example, if a human or some nature instruments produced some music by singing or playing, the method used in the invention should be able to analyze intelligently and give a result of what tones has been sang/played.

After analyzing the result spectrum data of human singing, I found human ear interpret the tone of the sound not by the where the peak frequency is, but by the distances between the peaks. For example when I sing “do re me fa so la xi”, even though some of their peak data in the spectrum overlap, the distances between them stay relatively the same. It is job of the invention to capture the data piece by piece (for example, ever ⅛^{th} of a second), and give an best estimate of what tone is played in that piece.

distances that falls on most of the peaks. In a computer world, everything is discrete, so the distance of 17.5 in the real world might be presented as 18, 17, 18 in computer numbers. In such case I average it to 17.5.

### BRIEF DESCRIPTION OF THE DRAWINGS

FIG. 1 is a block diagram of a tone recognizing apparatus embodying the invention;

FIG. 2 is a table showing a sample of musical tones and their peak positions in the spectrum, and the differences between the peak positions;

FIG. 3 is a diagram showing an example of 3 peaks of a tone, and how the recognizer calculates the final distance and weight from a suggested distance.

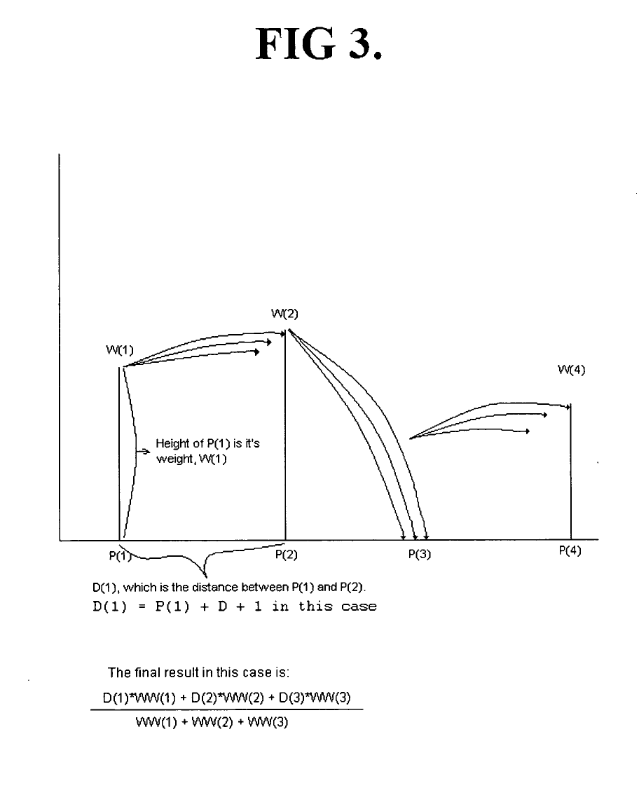

FIG. 4 is a diagram showing the notes ‘so’, ‘la’, ‘xi’ after spectrum analysis.

### DETAILED DESCRIPTION OF THE INVENTION

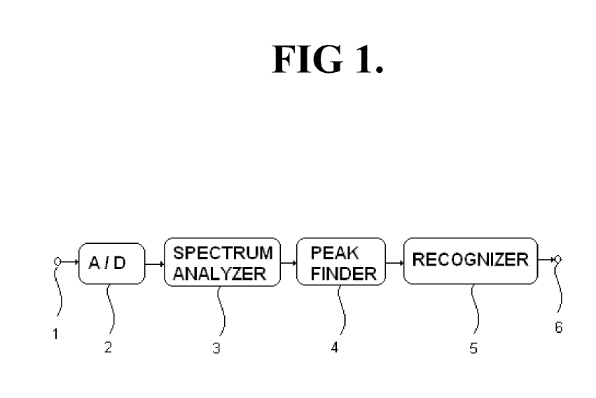

FIG. 1 is a block diagram showing an embodiment of the present invention. Reference numeral 1 denotes an input terminal of sound; 2 indicates an A/D converter; 3 indicates spectrum analyzer; 4 indicates a peak finder. 5 indicates a recognizer; 6 indicates an output terminal of the recognition result.

The sound supplied from the input terminal 1 is A/D converted by the A/D converter 2 and, after that, is analyzed by the spectrum analyzer 3 at some rate (⅛^{th} of a second, 1024 byte buffer at 8 khz in the examples shown) to convert to frequency domain, cut off any unnecessary spectrum range, for human tone recognition, 8 khz input sound format and 1024 byte buffer for FFT, only the data between 20 and 175 is necessary, also any spectrum value less than 1/10^{th} of the peak spectrum can be safely ignored. And the recognizer 5 will compute list of distance and their best weights and return the highest weight n items. The distance with the top weight is the dominant tone in the current sound piece.

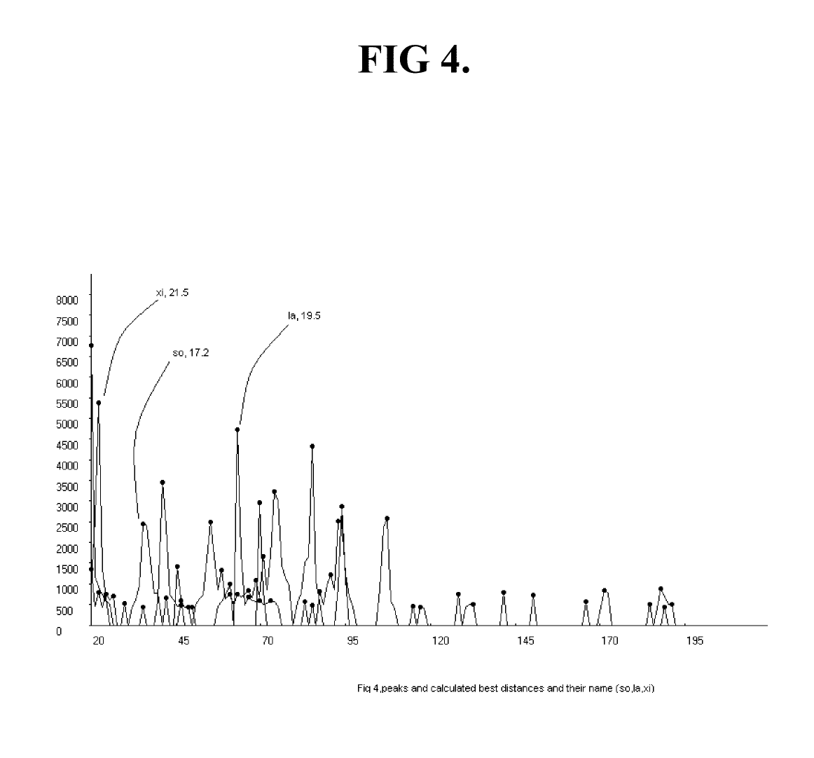

Peak finder (4) works by finding local peaks (FIG. 4 shows 3 tones with their peaks marked by a dot). There are many ways to find peaks, i.e. using a curve or threshold. For efficiency, the peak finder determines peaks by check both previous and next point of each spectrum data, if the current point's value is larger than both its neighbors, it is a peak.

Recognizer works by recursively check all distances against all peaks. To make it work faster, this invention checks the top N peaks against all other points. A N of 2 works fine for human tone. The distances of all top N peaks to all other peaks are used on each peak to calculate the best weight. For each distance (we shall call it suggested distance), on each of the N top peaks, the recognizer will do the following:

for peak at position n, P(n) and suggested distance D and −D (the genitive D is used to look back wards):
We will record the weight of a node WW(n) at each position extend forward and backward from peak P(n), also record the distance between possible peaks as D(n).

1. check value at position P(n)+D, P(n)+D−1, P(n)+D+1, the position that has the biggest value will be P(n+1), and D(n) will be either D if P(n)+D has the biggest value, or D−1 if P(n)+D−1 is the biggest value or D+1 if P(n)+D+1 is the biggest value. If all values are the same, D(n) will be D. The weight of this node WW(n) is:

if P(n)+D contains the biggest value, then WW(n)=W(n)+W(D)
if P(n)+D−1 contains the biggest value, then WW(n)=W(n)+W(D−1)
if P(n)+D+1 contains the biggest value, then WW(n)=W(n)+W(D+1).

2. Repeat step 1 with D till P(n+x)>=size of FFT buffer or no more peaks in this direction;

3. Repeat step 1 with −D till P(n+x)<=2 or no more peaks in this direction.

4. If there are only 1 peak available, the distance is between position of the peak and 0.

5. Calculate the total weight TW as TW=WW(n)+WW(n+1)+WW(n+2) . . . +WW(n+m)

6. Calculate the estimated distance De (this is the estimated frequency) as: De=(D(n)*WW(n)+D(n+1)*WW(n+1)+D(n+2)*WW(n+2)+ . . . +D(n+m)*WW(n+m))/TW

7. Repeat step 1 to 5 with all suggested distance and all peaks, and the De with the largest TW is our final result. The top N number of De can be returned if the user wish to do so.

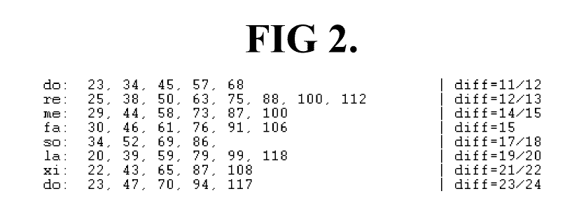

8. Optionally a table such as the one in FIG. 2 can be used to translate the value of De to musical notes, depend on application.

The present embodiment will now be described with respect to an example in which the recognition of tone ‘xi’ is calculated.

The tone ‘xi’ has peaks:

| position | value |
|---|---|
| 22 | 5127 |
| 43 | 1358 |
| 65 | 2817 |
| 87 | 2732 |

and for simplicity, I will check against only 1 peak instead of all top 3.

The biggest value is 5127, so position 22 is the top position.

the distances are:

22 to 43, suggested dist=21

22 to 65, suggested dist=43

22 to 87, suggested dist=65

and recognizer will try distances 21, 43 and 65 from position 22:

step 1: 22+21 landed on 43, the computed weight is 5127+1358=6485, distance is 21

step 2: 43+21 landed on 64. which has value 0. 64−1 is 63 which also has value 0, but 64+1=65 has value 2817, so computed weight is 1358+2817=4175, distance is 22

step 3: 65+21=86, which has value 0, 86−1=85, which also has value 0, 86+1=87, which has value 2732. so computed weight is 2817+2732=5549. distance is 22.

step 4: 22−21=1, but no more peaks after before 22, so processing is done.

Step 5: final weight is 6485+4175+5549=16209, final distance is (21*6485+22*4175+22*5549)/3/(16209)=(136185+91850+122078)/16209=21.59

So the final weight for suggested distance 21 is 16209 and the calculated distance with weight calculated in is 21.59.

Now repeat step 1 to 4 with distance 43:

step1: 22+43=65, since both position 64 and 66 is 0, the distance is 43 and weight is 5127+2817=7944.

step2: 65+43=108, it falls outside of available position so we abort the +43 direction.

Step3: 22−43<2, we abort the −43 direction and since there is only 1 distance, the finally weight is 7944 and final distance is 43.

The same is done for suggested distance 65. 22+65=87, nothing in the −65 direction and final weight is 5127+2732=7859, final distance is 65.

After all calculations are done, the top weight is the first one, distance 21.59, which is note ‘xi’ according to table in FIG. 2.

All the values above is obtained with 8 khz sound source and FFT buffer length of 1024. If the sound source is of different format or FFT buffer is of different length, the values should be adjusted accordingly. The effectiveness of the recognition method is not limited to the samples showing here.

What is claimed is:

1. A natural tone recognizing method comprising the steps of:
inputting a sound into a tone recognition apparatus;
Converting the sound clip into spectrum (frequency) domain and trim off unnecessary spectrum.
Find the peaks in the spectrum, then use a recognizing unit to find the best distances between the spectrum peaks (or high points) according to their weight (weight is calculated according to the strength of the spectrum)
Output the result.

2. A recognizing apparatus comprising:
Finding all distances between top N peaks of the spectrum and all peaks of the spectrum,
use the distances as the suggested distance, for each of them, step out with the distance from each of the top N peaks forward and backward, find each of the peaks that falls in the range of the distance, and try to move in that direction with the suggested distances till all peaks are reached or passed, and calculate the estimated distance (which maps to tone) by using all actual distances between each node weighted according to their weight.
